(19) United States
(12) Patent Application Publication
(10) Pub. No.: US 2004/0051174 A1
(43) Pub. Date: Mar. 18, 2004

(54) Electronic device with a voltage supply structure, semiconductor wafer with electronic devices, and associated production methods

(76) Inventors: Thomas Steinecke, Worth (DE); Franz Lohmair, FELDKIRCHEN-WESTERHAM (DE)

Correspondence Address: LERNER AND GREENBERG, P.A., POST OFFICE BOX 2480, HOLLYWOOD, FL, 33022-2480, US

(21) Appl. No.: 10/657,898

(22) Filed: Sep. 9, 2003

(30) Foreign Application Priority Data
Sep. 12, 2002 (DE) 102 42 324.5

(51) Int. Cl. H01L 23/48

(52) U.S. Cl. 257/739

(57) ABSTRACT

The invention relates to an electronic device and a semiconductor wafer and also to a method for producing the device and wafer. The electronic device comprises at least one semiconductor chip obtained from corresponding chip positions of a semiconductor wafer constructed according the invention. In this case, the semiconductor chip has two topmost metallization layers that have area-covering voltage supply structures, insulation layers arranged in between, and passage contacts to module regions of an integrated circuit. The voltage supply structure has a grid of supply interconnects arranged parallel to one another. This grid is rotated with respect to a grid of a subsequent metallization layer.

### BACKGROUND OF THE INVENTION

1. Field of the Invention

The invention relates to an electronic device and a semiconductor wafer having semiconductor chips with active top sides configured with metallization layers and insulation layers arranged alternately one above the other. Moreover, the invention relates to a method for producing the same.

U.S. Pat. No. 5,939,766 discloses a capacitor for integrated circuits in the region of metallization layers of a semiconductor chip. The capacitor has a comb-shaped interconnect structure, and interconnects of two comb structures that are arranged parallel intermesh with one another. In this case, the capacitance of the capacitor is determined by the distance between the intermeshing interconnects that are arranged parallel within a metallization layer. Moreover, U.S. Pat. No. 5,939,766 discloses a capacitor having a further comb structure of the same type, but the latter is arranged in a metallization layer arranged underneath. The total capacitance of the capacitor is determined first by the distances between the intermeshing comb structures of each metallization layer and additionally by the distance between the metallization layers. To that end, the parallel interconnect structures are oriented in the same direction in the two metallization layers. What is thus achieved is that a capacitor of this type requires only a fraction of the surface of a semiconductor chip for a sufficient capacitance of the capacitor. The remaining area of the metallization layer can be used for signal interconnects and supply interconnects.

One disadvantage of a semiconductor chip of this type is a high area requirement on account of the arrangement of capacitor interconnects, supply interconnects, and signal interconnects in each of the metallization planes. The result is that an automatic wiring using “place+route” programs is made more difficult or is in many cases impossible. By using automatic “place+route” programs, called PR (place+route) programs hereinafter, the functional units of integrated circuits such as NOR gates, AND gates, NAND gates, operational amplifiers, impedance modules, TTL modules and others can be arbitrarily placed on one another and can be automatically wired to one another. However, this presupposes a uniform metallization layer thickness per metallization layer, which causes a high area requirement particularly in the dimensioning of supply lines at the same plane as signal lines and at the same plane as the capacitor structure disclosed in U.S. Pat. No. 5,939,766.

### SUMMARY OF THE INVENTION

It is accordingly an object of the invention to provide an electronic device, a semiconductor wafer, and associated production methods which overcomes the above-mentioned disadvantages of the prior art apparatus and methods of this general type.

In particular, it is an object of the invention to provide an electronic device having a semiconductor chip and also a semiconductor wafer in which the layer sequence of the metallization layers is optimized with regard to the total area requirement and an automatic wiring can be effected using PR programs.

With the foregoing and other objects in view there is provided, in accordance with the invention, an electronic device having a semiconductor chip with an active top side having metallization layers and insulation layers arranged thereon alternately one above the other. In this case, the metallization layers have voltage supply structures and/or signal line structures. Arranged in the insulation layers are passage contacts, which connect the voltage supply structures and the signal line structures to contact areas of the active top side of the semiconductor chip. The topmost metallization layers have area-covering voltage supply structures and insulation layers arranged in between with through contacts to module regions of the integrated circuit. In this case, at least two mutually insulated voltage supply structures are provided for a low and for a high supply potential. The voltage supply structures of the upper metallization layers in each case have grids of supply interconnects arranged parallel to one another. Successive grids of successive metallization layers are rotated relative to one another. Metallization layers for signal line structures are arranged below the metallization layers for a voltage supply.

An electronic device of this type having a semiconductor chip of this type has the advantage that the layer by layer separation of area-covering voltage supply structures on upper metallization layers and—arranged underneath—metallization layers with signal line structures enables the metallization thickness to be adapted to the respective tasks of the structures. Thus, significantly thicker metal structures may be provided in the topmost metallization layers in order to reduce the area requirement for the voltage supply structures. In the metallization layers arranged underneath, the metal thicknesses may be extremely small and adapted to the weak signal currents.

A further advantage is that now a voltage supply is available for the entire area of the semiconductor chip in an area-covering manner, thereby enabling an EMC-optimized wiring—which can be generated automatically—using PR programs. The functional modules of the lower metallization layers can be supplied with voltage without having to provide a wiring with an additional area requirement between the signal line structures of the functional modules. Rather, the functional modules are supplied from “above” from power supply rails or from contact wires. Finally, the freely selectable thickness of the metallization of the upper metallization layers enables a low-impedance supply of the functional modules of the integrated circuit, thereby also minimizing the risk of voltage dips in the voltage supply structure.

A further advantage of an electronic device of this type having a semiconductor chip, which has voltage supply structures on its topmost metallization layers, is that by capacitive coupling, a charge buffer is created by the grid-type supply interconnects arranged parallel to one another, thereby creating rapid and local switching currents for the underlying functional modules and for the integrated circuit structures of the semiconductor chip.

In a preferred embodiment of the invention, the semiconductor chip has an integrated circuit subdivided into functional module regions. To that end, each module region is connected via corresponding electrodes or connection lines and via through contacts to the voltage supply structures of the upper metallization layers. Consequently, the functional module regions can be arranged closely adjacent to one another on the semiconductor chip, especially as there is no need for additional areas for passing supply voltages via corresponding voltage supply structures to the individual module regions of the integrated circuit between the functional modules, rather the entire voltage supply is effected via the area-covering voltage supply structure of the upper metallization layers and via through contacts to the electrodes or connection lines of the module regions.

What is provided as the semiconductor chip for the electronic device is a silicon chip made of monocrystalline material which has an integrated circuit in regions of its active top side. The contact areas of this integrated circuit are electrically connected to the interconnects arranged thereabove via through contacts through the insulation layers. The electrical connections can be wired automatically using PR programs. Such an automatic capability for wiring the voltage supply structures of the upper metallization layers has the advantage of arbitrarily extending the functions of the integrated circuit by attaching and automatically wiring further module regions without the need for additional fundamental manual development measures.

In a further embodiment of the invention, the supply interconnects arranged parallel to one another within a metallization layer alternately have different electrical supply potentials. What is achieved by this measure is that the side areas of the supply interconnects arranged parallel to one another serve, by virtue of their capacitive coupling, as a charge buffer for the functional modules of the integrated circuit, which improves a rapid local provision of switching currents. In this case, the possible thicker embodiment of the metallization of the upper metallization layers compared with the lower metallization layers has a capacitance-boosting effect for the signal line. The thicker the metallization of the voltage supply structures, the greater the possibility of capacitive coupling of supply interconnects arranged parallel at different electrical supply potentials. In addition to the thickness of the metallization, the distances between the supply interconnects that are arranged parallel to one another within a metallization layer and that have alternate supply voltages may also contribute to increasing the capacitive coupling by being dimensioned in such a way that they have an electrical capacitance that is as high as possible with sufficient dielectric strength.

In a further embodiment of the invention, the supply interconnects arranged parallel to one another within an upper metallization layer are at the same electrical supply potential. No charge buffer is created within one and the same metallization layer, but rather the grids of the subsequent metallization layers that are rotated with respect thereto are at different supply potentials, so that the mutually opposite crossover areas form a charge buffer by virtue of their capacitive coupling areas and thus enable a rapid local provision of switching currents. To that end, in an advantageous manner, the thickness of the insulation layers between the topmost metallization layers may be dimensioned in such a way that the crossover areas of the grids of two voltage supply structures that are arranged one above the other form a highest possible electrical capacitance with sufficient dielectric strength.

The metallization layers may have polycrystalline silicon, copper, aluminum, nickel or alloys of copper, of aluminum or of nickel. The polycrystalline silicon is highly doped as metallization layer material, so that its charge carrier concentration is above 10²¹ cm⁻³, which already approaches the charge carrier concentration of metals. In this case, it is preferable to use polycrystalline silicon as a metallization layer in the lower metallization layers for the signal line, and it has proved to be successful particularly as gate electrode material.

Copper and its alloys are increasingly being used for signal interconnects, especially since the risk of migration of copper and copper alloys is minimized in comparison with aluminum, and interconnects made of copper or copper alloys can be produced with a width in the submicron range. Nickel and nickel alloys are often used as diffusion stop layers both for voltage supply structures and for signal line structures with respect to copper interconnects. Aluminum and its alloys preferably form thick voltage supply interconnects with a high capacitive coupling.

The insulation layer material used is advantageously silicon dioxide and/or silicon nitride, which, on account of their high dielectric strength in extremely thin layers in some instances below 1 μm, already have a sufficient dielectric strength between the metal layers for supplying integrated circuits. In addition, the insulation layer material used may also be polymer plastics such as polyimide, which, however, on account of their lower dielectric strength, are provided with a larger thickness than the ceramic layers made of silicon dioxide and silicon nitride.

The present invention furthermore relates to a semiconductor wafer having a plurality of semiconductor chip positions, which are arranged in rows and columns on an active top side of the semiconductor wafer. To that end, the semiconductor wafer has—arranged alternately one above the other—patterned metallization layers and insulation layers with through contacts in each chip position. The contact areas on the active top side of the semiconductor wafer are connected to the voltage supply structures and/or the signal line structures via the passage contacts of the insulation layers. The upper metallization layers of the semiconductor wafer form area-covering voltage supply structures with insulation layers arranged in between in each of the semiconductor chip positions. To that end, mutually insulated voltage supply structures have at least a low and a high supply potential and form a grid of supply interconnects arranged parallel to one another. Successive grids in a stack of metallization layers are rotated with respect to one another. The lower metallization layers each have signal line structures.

The grids of the voltage supply interconnects that are rotated with respect to one another preferably form an angle of rotation of 90° for metallization layers arranged one above the other. Opposite crossover areas thus form between the voltage supply structures, and represent a charge buffer because of their coupling capacitance. The wiring of the voltage supply structures can be performed automatically by PR programs, especially as it is unambiguously the case that either only voltage supply interconnects or only signal interconnects occur within a metallization layer, and especially since the interconnects are provided in an area-covering manner in each case.

It is only in exceptional cases that signal interconnects can also additionally be incorporated into the upper metallization layers, in particular when it is necessary to realize short connections to the electrodes of the integrated circuit in the semiconductor chip and signal line routings via the lower metallization layers add up to an excessively large length.

Each semiconductor position of the semiconductor wafer has an integrated circuit subdivided into functional module regions. Each module region is connected via its electrodes or connection lines and via the passage contacts to the voltage supply structures of the upper metallization layers. The advantages of an arrangement of this type are the same as have already been elucidated more precisely for the semiconductor chip. The further advantageous embodiments of the electronic device having a semiconductor chip can also be applied to the semiconductor chip positions of a semiconductor wafer and the discussion of the associated advantages is omitted at this point in order to avoid repetition.

With the foregoing and other objects in view there is provided, in accordance with the invention, a method for producing a semiconductor wafer having a plurality of semiconductor chip positions and having at least two upper metallization layers as voltage supply structures with parallel supply interconnects in each of the semiconductor chip positions. The parallel supply lines of the topmost metallization layers are oriented transversely with respect to the parallel supply lines of the metallization layers arranged underneath. The method includes the following steps: A semiconductor wafer having a plurality of semiconductor chip positions is provided. The semiconductor chip positions have metallization layers with signal line structures and insulation layers arranged in between with passage contacts. The signal line structures are connected via the passage contacts to contact areas on the active top side of the semiconductor wafer. A closed metallization layer is applied to a topmost insulation layer of the signal line structures. The closed metallization layer is patterned to form a grid of parallel supply interconnects as a first voltage supply structure. The position of the supply interconnects is designed automatically by “place-route” programs. An insulation layer is applied to the voltage supply structure with passage contacts to contact areas on the active top side. The positioning of the passage contacts is effected using a photolithography mask that is designed automatically by “place-route” programs. A further metallization layer with a grid of parallel supply interconnects is applied and patterned. The grid of parallel supply interconnects is arranged in a manner rotated with respect to the direction of the first voltage supply structure and the position of the grid of parallel supply interconnects is designed automatically by “place-route” programs. The method also includes applying a passivation layer with contact pads being left free or uncovered. The contact pads are electrically connected to passage contacts.

This method has the advantage that it provides a semiconductor wafer, in particular a semiconductor wafer made of a single crystal of silicon, with metallization structures having, as a topmost metallization structure, voltage supply structures that have been designed automatically by PR programs. By virtue of the area saving, because voltage supply interconnects no longer run besides signal interconnects in identical metallization layers, but rather all the voltage supply structures are realized in separate upper metallization layers, a higher number of semiconductor chip positions can be provided on wafers of the same size having a diameter of 300 cm, for example. Furthermore, a greater packing density of electronic switching functions in the semiconductor wafer is achieved at the same time.

With the foregoing and other objects in view there is provided, in accordance with the invention, a method for producing an electronic device by separating the semiconductor wafer produced into semiconductor chips. The method includes the following steps. The semiconductor chips are applied to a leadframe with a plurality of device positions. Bonding connections are produced between the leadframe and the contact pads of the semiconductor chips in each device position. The semiconductor chips with bonding connections are produced in a plastic housing with external contacts in each device position. The leadframe is separated into a plurality of electronic devices.

This method is associated with the advantage that bonding connections according to predetermined plans can be carried out simultaneously for a plurality of semiconductor chips on a leadframe, and a plurality of electronic devices can also be packaged simultaneously on one and the same leadframe. Devices with a completely identical housing then result after the leadframe has been separated into individual electronic devices.

To summarize, it must be emphasized that future large scale integrated digital circuits fabricated in multilayer metallization processes will have a large number of available metal layers making it possible, according to the invention, to distinguish between the signal wirings and the voltage supply wirings, to provide the upper metal layers for voltage supply structures, and to reserve the underlying metal layers exclusively for the signal line structures.

To that end, the topmost metal layers may serve for the voltage supply of the individual functional modules of the integrated circuit of a semiconductor chip. The modules of the integrated circuit that lie below the supply layers thus tap off their supply voltage like “locomotives” from a “contact wire”. The major advantage of such “contact wire realization” of the module supply is its neutrality with respect to area. Whereas at present, for lack of available metal layers, the module supply is arranged in channels between the modules and additional chip area is thus required, using the present invention, the module supply can be arranged above the modules given the availability of sufficient metal layers. The modules themselves adjoin one another directly and without intermediate channels. Consequently, it is possible to realize an electronic device which, for the same functionality, requires a smaller chip area or, for the same chip area, now has a higher functionality and thus also a higher circuit density. Should the power requirement of the modules increase further, it is possible to accommodate as many voltage supply structures as desired one above the other in mutually insulated metallization layers.

If only two supply potentials are offered, then a supply concept can be realized in its entirety with a minimum of two metal layers. The top two metal layers are used for the voltage supply, and the supply is not effected via the module wiring, so that the voltage supply lines do not run within the signal wiring for the functional modules. Consequently, the functional modules are situated completely below the voltage supply layers.

Automatic wiring tools such as PR programs have preferred directions for the routing of the signal and supply lines. To that end, the metal tracks of the voltage supply structures are preferably routed orthogonally to one another in each case in two metallization planes lying one above the other. Consequently, the crossover of metal tracks is possible only in overlying or underlying planes. The inventive supply structure takes account of this requirement of automatic PR programs and has, in the at least two metallization planes available for the voltage supply in each case, supply tracks that are preferably rotated orthogonally to one another.

A low-impedance supply of the functional modules with a minimization of the voltage dips is achieved by the invention.

On account of the demand for automatic wiring, it is not possible to provide so-called supply areas that in each case provide a completely closed metallization layer for one of the potentials. In which case, it would be necessary to provide perforations in the bottom supply layer in order to lead through the supply voltage of the upper layer in insulated fashion through the plate for the second supply potential. Such a plate-type provision of voltage supply structures is associated with high manual outlay since PR programs are not provided for this.

With the patterning, according to the invention, of voltage supply lines that run parallel to one another, are arranged in grid form and are rotated relative to one another in successive metallization layers, it is possible to satisfy the boundary conditions for an automatic design of wiring routings by PR programs. The availability of very many lines running parallel means that it is also possible to satisfy the requirement for a high current-carrying capacity of the voltage supply structures.

At the same time, the present invention also provides, in addition to a high current-carrying capacity, a charge buffer through capacitive coupling. The charge buffers entail an advantage with regard to the current that can be supplied for fast switching operations. High-frequency components of the charge current, in particular, can then be provided in situ by the buffer. The transmission of the high-frequency switching currents and the harmonic electromagnetic oscillations thereof into regions outside the semiconductor chip is avoided in this way. As a result, the inventive semiconductor chip affords an advantage for electromagnetic compatibility, especially as high-frequency switching currents are not transmitted on structures, such as structures of an adjoining printed circuit board, for example, and, consequently, also do not cause interference there.

In modern IC fabrication processes, the vertical coupling capacitance is in some instances less than the lateral coupling capacitance between interconnects running parallel, especially as the width of the metal tracks is continually being reduced in comparison with the height thereof. Whereas usually running the signal wiring interconnects in parallel is avoided because of the risk of crosstalk, here the situation in which voltage supply interconnects run parallel yields a high capacitive coupling which is advantageous because of the provision of a charge buffer for fast circuit operations. Consequently, an alternate arrangement of parallel voltage supply lines with positive and negative potential in a metallization layer leads to an advantageous high capacitive coupling of the two voltage potentials.

Other features which are considered as characteristic for the invention are set forth in the appended claims.

Although the invention is illustrated and described herein as embodied in an electronic device with a voltage supply structure and a method for producing it, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic plan view of a first embodiment of a semiconductor chip of an electronic device;

FIG. 2 is a diagrammatic cross sectional view of a layer plan of a second embodiment of a semiconductor chip with a plurality of metallization layers;

FIG. 3 is a diagrammatic cross sectional view of a layer plan of the semiconductor chip of FIG. 2 at an angle of 90° to a layer cross section of FIG. 2;

FIG. 4 is a diagrammatic perspective view of a third embodiment of the invention and specifically shows a detail of the upper metallization layers with passage contacts;

FIG. 5 is a diagrammatic perspective view of a detail of the upper metallization layers with passage contacts of the embodiment of FIG. 4;

FIG. 6 is a diagrammatic perspective view of a fourth embodiment of the invention and specifically shows a detail of the upper metallization layers with passage contacts;

FIG. 7 is a diagrammatic perspective view of a fifth embodiment of the invention and specifically shows a detail of the upper metallization layers with passage contacts; and

FIG. 8 is a diagrammatic perspective view of a semiconductor wafer with a plurality of semiconductor chip positions for electronic devices constructed according to the invention.

### DESCRIPTION OF THE PREFERRED EMBODIMENTS

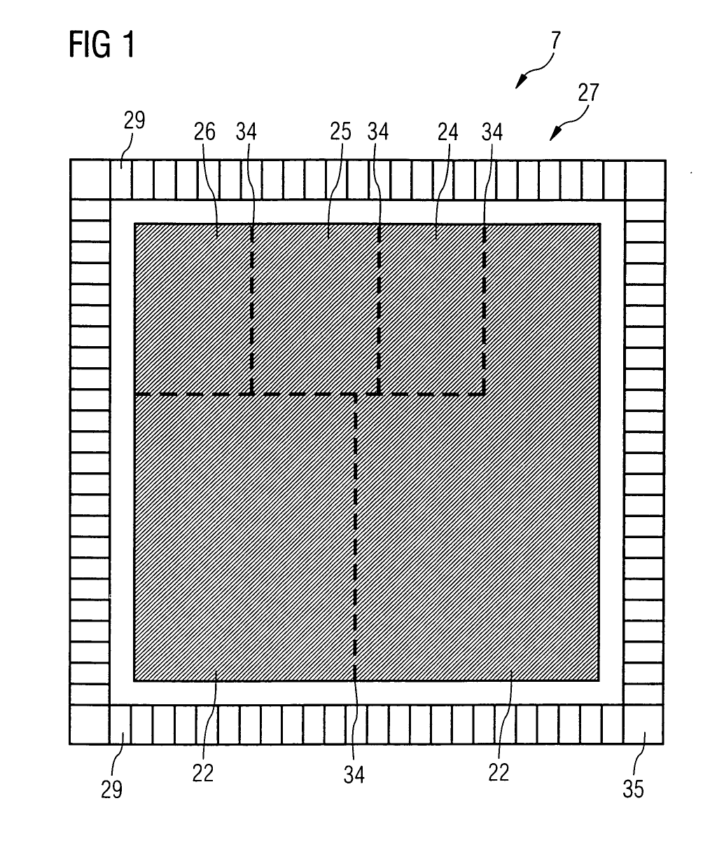

Referring now to the figures of the drawing in detail and first, particularly, to FIG. 1 thereof, there is shown a diagrammatic plan view of a semiconductor chip 7 of a first embodiment of an electronic device. The top side of the semiconductor chip exhibits five module regions 22-26, which adjoin one another directly. Voltage supply lines are not provided between the module regions 22-26. The boundaries of the module regions 22-26 are marked by the broken lines 34. The voltage supply of the semiconductor chip 7 is effected via upper metallization layers (not marked here) which have voltage supply lines arranged parallel to one another and extend in an area-covering manner over the entire shaded area in FIG. 1. The edge region 35 of the semiconductor chip 7 is provided for contact pads 29, which are connected to the electrodes of the integrated circuit 27 via passage contacts (not visible here) and via interconnects (not visible here) via the metallization layers.

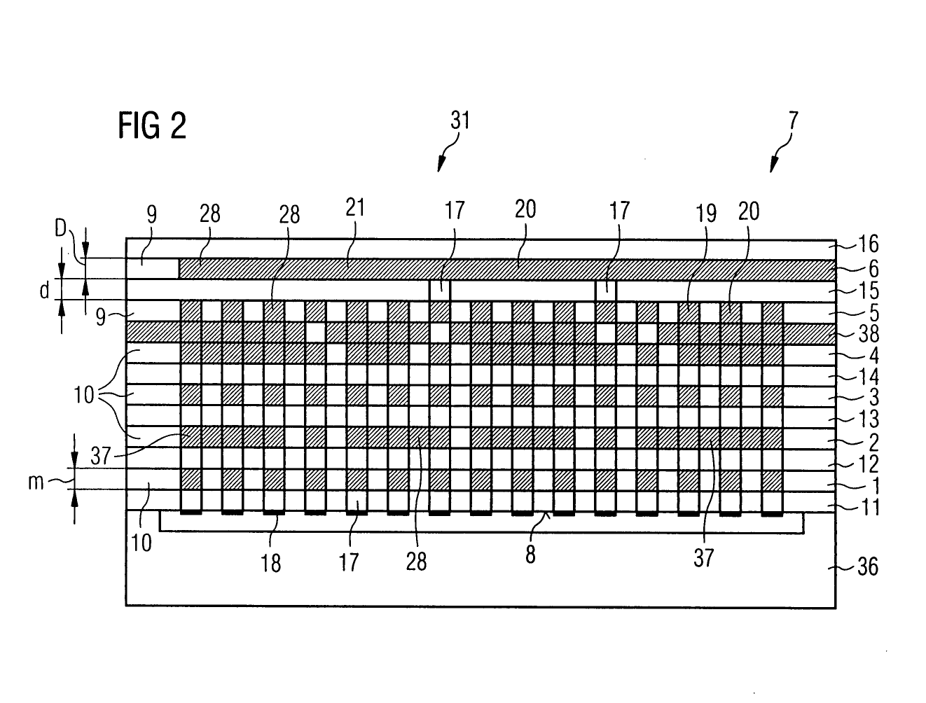

FIG. 2 shows a diagrammatic cross sectional view of a second embodiment of the invention, namely, of a layer plan of a semiconductor chip 7 with a plurality of metallization layers 1-6. A plurality of metallization layers 1-6 are arranged on a semiconductor substrate 36. Before the semiconductor substrate 36 is separated into a plurality of semiconductor chips 7, it can comprise a monocrystalline silicon wafer having a plurality of semiconductor chip positions 31 on its active top side 8. In each of the semiconductor chip positions 31, contact areas 18 are arranged in the region of the active top side 8. These contact areas 18 form the electrodes of the individual semiconductor components of the integrated circuit. Said electrodes are interconnected to form functional module regions of the integrated circuit, as can be seen in FIG. 1. The first four metallization layers 1-4 have signal lines which are connected via passage contacts 17 among one another and to the contact areas 18 of the semiconductor substrate 36.

In this exemplary embodiment, the thickness m of the signal interconnects of the metallization layers 1-4 is significantly less than the thickness D of the upper metallization layers with supply interconnects 20 running parallel. In the diagrammatic cross section of FIG. 2, from the topmost supply interconnect 20, only an elongate supply interconnect 20 of the supply interconnects that are arranged parallel and in grid form is revealed in cross section, while from the metallization layer 5 arranged underneath, all the supply interconnects 20 running parallel can be seen in cross section. Since this is only a layer plan, the cross section of each supply interconnect 20 is only indicated symbolically and does not correspond to the true size. The same applies, in particular, to the thickness d of the insulation layer with passage contacts 17 arranged between the metallization layers.

While the thickness m of the lower metallization layers 1-4 for the signal wiring is in the range of between 0.3 and 2 μm, for example, the supply interconnects 20 have, for example, a thickness D of between 2 μm and 15 μm in this embodiment of the invention. Arranged between the metallization layers 1-6 are insulation layers 11-15 which have passage contacts 17 in order to connect together the interconnects 28 for each module region 22-26 shown in FIG. 1. Arranged between the two upper metallization layers 5 and 6 for a voltage supply and the metallization layers 1-4 arranged underneath for the signal line within the individual module regions is a contact wire layer 38. The contact wire layer 38 includes elongate passage contacts that act like a “contact wire for a locomotive” to distribute the supply voltage of the upper metallization layers 5 and 4 between the underlying module regions with their signal line structures 10. The thickness of the “contact wire layer” corresponds to the thickness D of the upper metallization layers 5 and 6 with their supply interconnects 20.

A layer cross section of this type, as is shown in FIG. 2, is based on the principle of interconnects 28 which are arranged at right angles to one another and can be connected among one another via passage contacts 17. A layer cross section of this type can therefore be planned and designed using automatic wiring programs, such as a PR program, without manual intervention, with the result that any desired extensions of the functionality of the integrated circuit become possible.

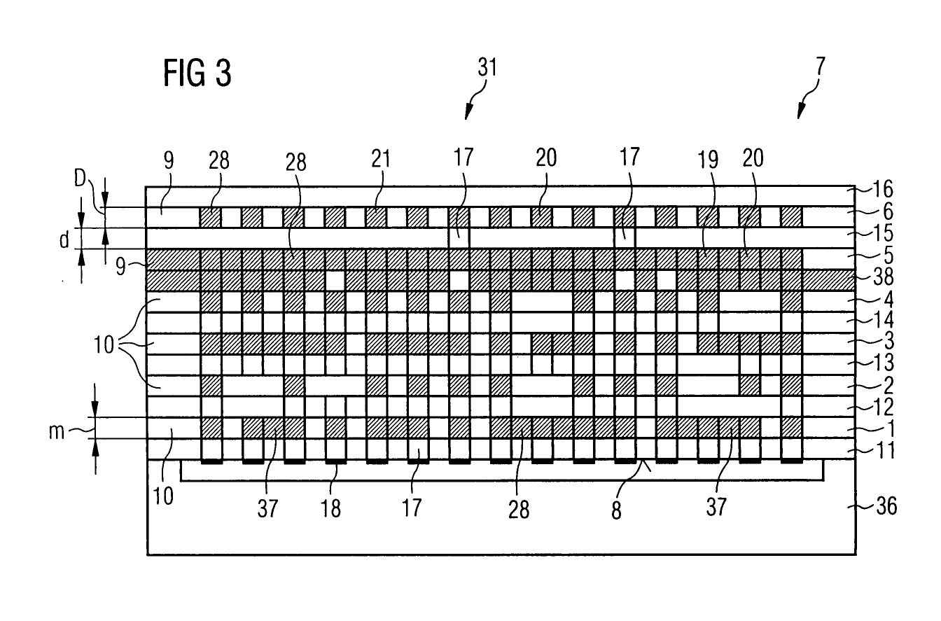

FIG. 3 shows a diagrammatic cross section of a layer plan of the semiconductor chip 7 of FIG. 2 at an angle of 90° to the layer cross section of FIG. 2. This diagrammatic cross section of FIG. 3, which is illustrated orthogonally to the cross section of FIG. 2, now shows an individual supply interconnect of the metallization layer 5 in cross section, while the topmost metallization layer shows all cross sections of the voltage supply structure 9 of the topmost metallization layer 6. These two cross sections of FIGS. 2 and 3 show that the voltage supply structure 9 of the upper two metallization layers 5 and 6 each have a grid comprising supply interconnects 20 arranged parallel to one another. These grids are arranged at right angles or orthogonally to one another and are connected via passage contacts 17 to the underlying contact wire layer 38 and the downstream module regions.

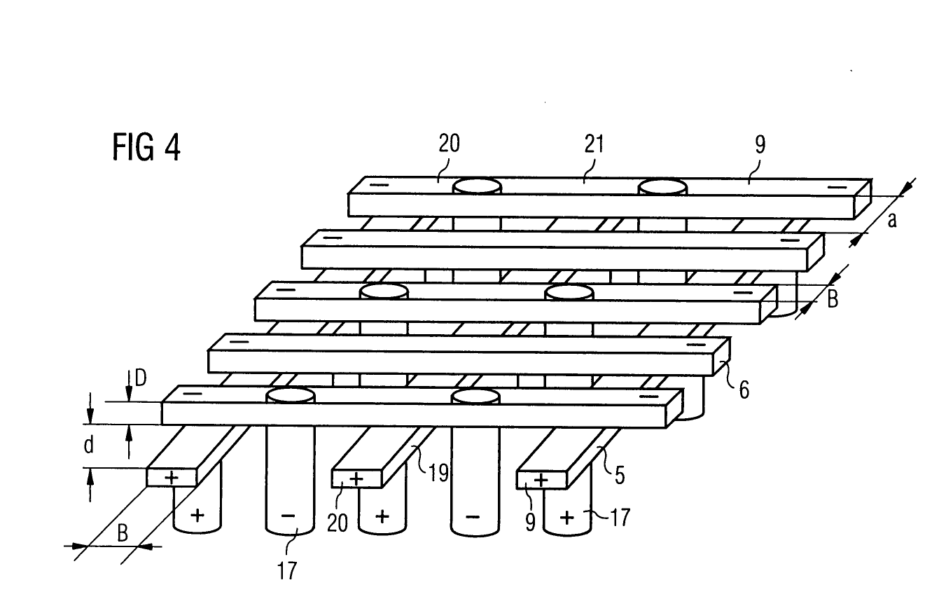

A detailed illustration of the upper two metallization layers 5 and 6 with their passage contacts 17 through the insulation layer 15 situated in between is shown in FIGS. 4 to 7 below. Components with the same functions as in the previous Figs. are identified by the same reference symbols in FIGS. 4 to 7 and are not discussed separately.

FIG. 4 is a diagrammatic perspective view of a third embodiment of the invention, and specifically shows a detail of the upper metallization layers 5 and 6 with passage contacts 17. The topmost metallization layer 6 has supply interconnects 20 which are arranged parallel to one another and are at the same negative electrical potential. The thickness D of each supply interconnect 20 is between 2 and 15 μm the width B depends on the maximum current to be passed through the supply interconnects 20. Passage contacts 17 proceed from the supply interconnects 20 of the upper metallization layer 6, which passage contacts are connected to the contact wire layer (not shown here), as is shown by FIGS. 2 and 3. The lower second metallization layer 5 has supply interconnects which are at positive potential and form a grid 21, which is oriented orthogonally to the grid of the topmost voltage supply structure 9. Passage contacts 17 lead from these supply interconnects through the underlying insulation layer. The positions of the passage contacts 17 that are shown here can be automatically defined and optimized using PR programs and need not correspond to the positions that are illustrated in FIG. 4.

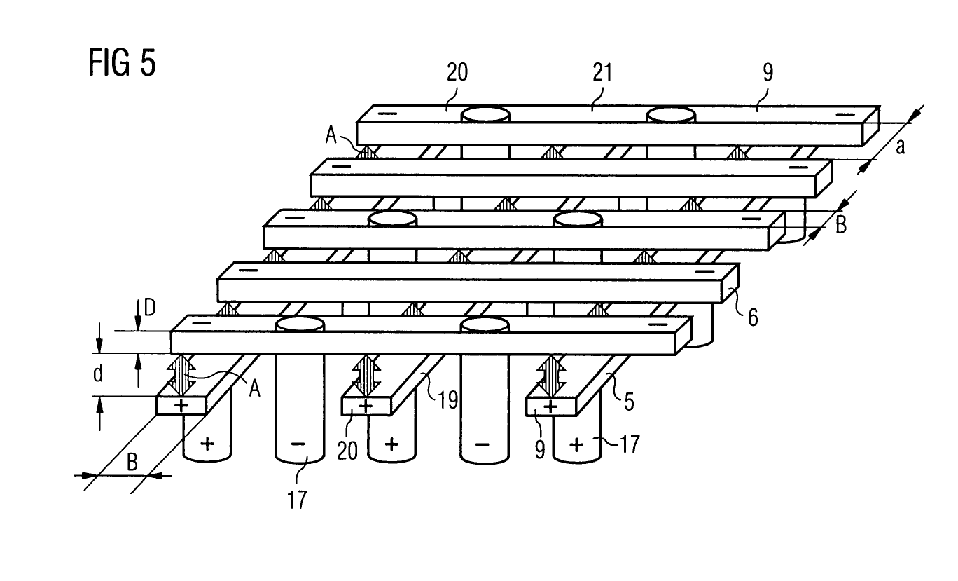

FIG. 5 is a diagrammatic perspective view of the embodiment of FIG. 4, specifically of a detail of the upper metallization layers 5 and 6 with passage contacts 17. In FIG. 5, arrows A, which are arranged at the locations at which a capacitive coupling effect occurs, show that, on account of the potential difference between the upper voltage supply structure 9 in the metallization layer 6 and the lower voltage supply structure 9 in the metallization layer 5, only the crossover areas in each case contribute to a capacitive coupling. The distance “a” between the interconnects running parallel makes no contribution whatsoever to a capacitive coupling, so that here only the thickness “d” of the insulation layer arranged between the interconnect grids arranged transversely with respect to one another influences the capacitive coupling. In this case, it is necessary to take account of the fact that the thickness d ensures a sufficient dielectric strength between the potential difference of the negative potential of the topmost metallization layer 6 and the positive potential of the underlying metallization layer 5.

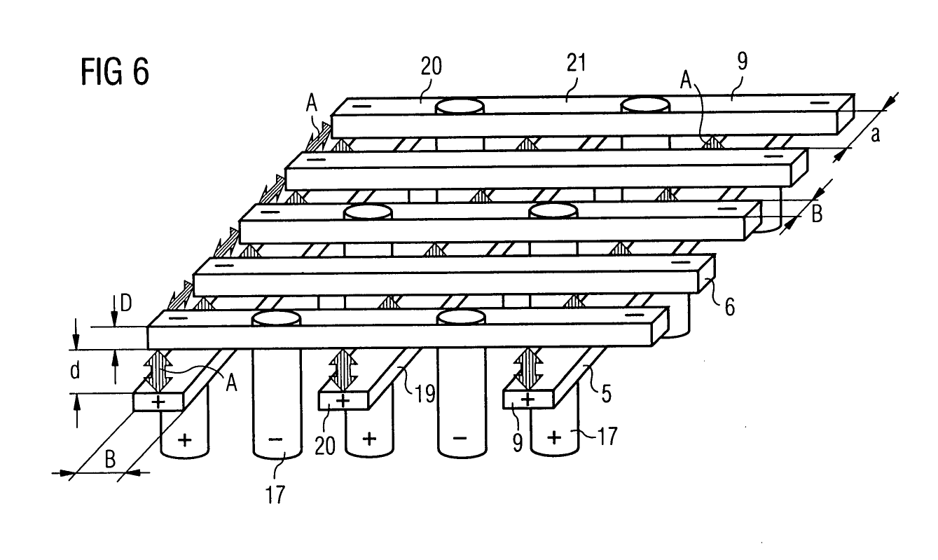

FIG. 6 shows a fourth embodiment of the invention, specifically, a diagrammatic perspective view of a detail of the upper metallization layers 5 and 6 with passage contacts 17. In this embodiment of the invention, as in the third embodiment of the invention of FIGS. 4 and 5, passage contacts 17 are provided which are connected both to the lower metallization layer 5 and to the upper metallization layer 6. However, the potentials of the supply interconnects 20 of the upper metallization layer 6 are alternately provided with a low potential or a high potential, so that their longitudinal sides lying opposite one another separated by the distance a contribute to the capacitive coupling. The underlying interconnects 20 arranged at right angles to the overlying supply interconnects 20 have the same positive potential and their distances are also significantly larger than in the case of the topmost metallization layer, since the passage contacts 17 of the overlying metallization layer 5 are arranged between the respective supply interconnects.

No charge buffer forms in the lower metallization layer 5 because the supply interconnects 20 have the same potential and also because of the high distance between the supply interconnects 20 of the lower metallization layer, so that only a contribution by the opposite crossover areas at a different potential forms a further contribution to the coupling capacitance. However, a greater effect than in the third exemplary embodiment of the invention can already be achieved through the significantly higher coupling capacitance which can be achieved because of the opposite longitudinal sides of the upper supply interconnects.

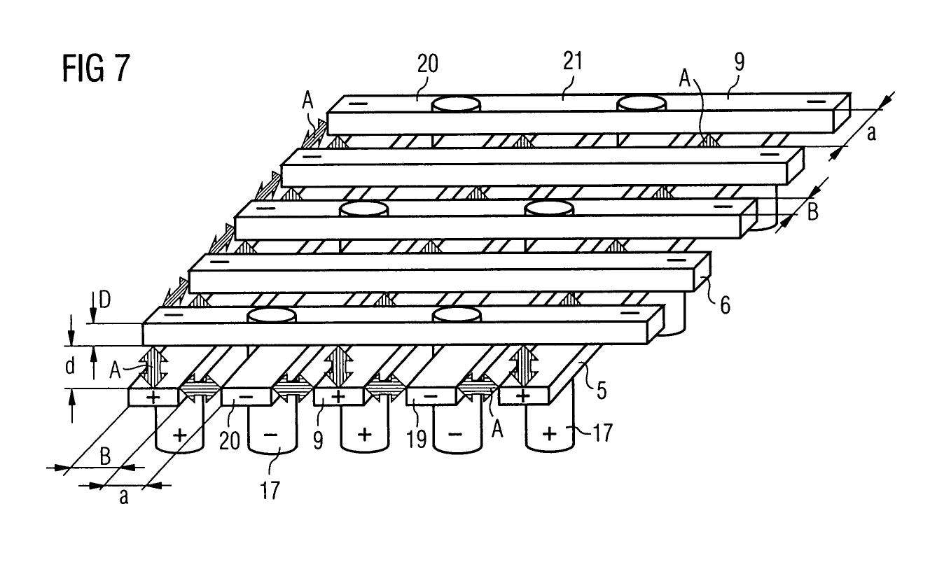

FIG. 7 shows a fifth embodiment of the invention, and specifically shows a diagrammatic perspective view of a detail of the upper metallization layers 5 and 6 with passage contacts 17. The embodiment shown in FIG. 7 achieves the greatest capacitive coupling between the supply interconnects 20 because, both in the topmost metallization layer 6 and in the metallization layer 5 arranged underneath, the distance a between the supply interconnects 20 is in each case optimized in such a way that all the longitudinal sides of the supply interconnects 20 contribute to the formation of a high coupling capacitance. By contrast, the number of crossover areas is lower than in the third exemplary embodiment, but higher than in the fourth exemplary embodiment, which can be seen from the arrows A.

This highest capacitive coupling, which advantageously enables a rapid provision of switching currents without, by way of example, high-frequency switching currents interfering with the surroundings of the electronic device, is achieved by dispensing with passage contacts 17 to the topmost metallization layer 6. Instead, from the lower metallization layer 5, both potentials are offered alternately to the module regions arranged underneath via passage contacts. In addition, the supply interconnects 20 of the topmost metallization layer are alternately put at a different potential, so that the upper metallization layer increases the total coupling capacitance essentially because of its mutually opposite longitudinal sides of the supply interconnects 20. Both the supply interconnects 20 of the upper metallization layer 6 and the supply interconnects 20 of the underlying metallization layer 5 have an identical optimized distance “a” which ensures the dielectric strength and simultaneously provides for a high lateral coupling capacitance.

The current which can be conducted through the grid of the fifth embodiment of the invention is determined by the sum of the supply line cross sections of the mutually opposite grids 19 and 21. Given a maximum current—assumed for avoiding electromigration—for aluminum interconnects of 1 mA per micrometer interconnect width, it is possible, by using an area-covering grid with a grid area of 25 mm², taking account of predetermined design rules, to feed a supply current of about 1.5 to 2 A to the semiconductor chip, which is approximately a factor of 5 to 10 above a realistic current requirement of present-day integrated circuits of this size.

The resulting coupling capacitance of the fifth embodiment of the invention, as is shown by FIG. 7, can be estimated as follows:

Cᵥ=X·Y·14 pF,

where X and Y denote the length and width, respectively, of the grid structure in mm and Cᵥ is the effective vertical capacitance between the crossover areas, and, moreover.

C₁=X·Y·112 pF,

where X and Y denote the length and width, respectively, of the grid structure in mm and C₁ is the effective lateral capacitance between side areas of the supply interconnects.

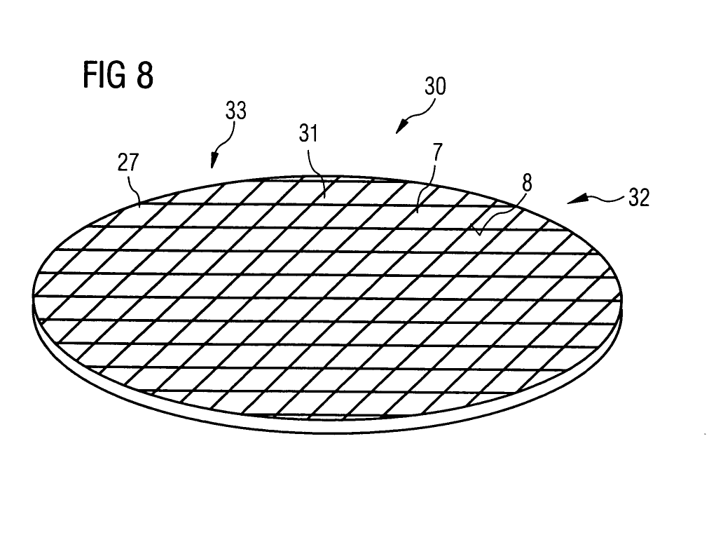

FIG. 8 shows a semiconductor wafer 30 having a plurality of semiconductor chip positions 31 for electronic devices of the invention. Semiconductor wafers 30 of this type are increasingly becoming commercial objects and are supplied to corresponding customers in tested and untested form. In the case of tested semiconductor wafers 30, the non-functional semiconductor chips 7 are marked as a precaution in order that they are not processed further after the semiconductor wafer 30 has been separated into a plurality of semiconductor chips 7. By contrast, the functional semiconductor chips 7 are fed for further processing. The semiconductor wafer 30 itself has the semiconductor chip positions 31 in rows 32 and columns 33, which run at right angles to one another, so that the semiconductor chips 7 can be singled out by a simple sawing technology. A semiconductor wafer 30 of this type already has all the wiring planes of the invention in each semiconductor chip position 31, so that, after the separation into individual semiconductor chips 7, all that has to be carried out is the application to a leadframe, the bonding of bonding connections and packaging in a corresponding housing, in order to produce an electronic device according to the invention.

We claim:

1. An electronic device, comprising:
a semiconductor chip having an active top side with a plurality of contact areas;
said semiconductor chip having a plurality of metallization layers and a plurality of insulation layers configured alternately one above another on said active top side;
said plurality of metallization layers having a plurality of voltage supply structures and/or a plurality of signal line structures;
said plurality of insulation layers formed with a plurality of passage contacts connecting said plurality of voltage supply structures and/or said plurality of signal line structures to said plurality of contact areas of said active top side;
said plurality of metallization layers including topmost metallization layers having area-covering ones of said plurality of voltage supply structures;
said topmost metallization layers having ones of said plurality of passage contacts connected to said plurality of contact areas;
said topmost metallization layers having at least a first one of said plurality of voltage supply structures for a low supply potential and a second one of said plurality of voltage supply structures for a high supply potential;
said first one of said plurality of voltage supply structures being insulated from said second one of said plurality of voltage supply structures;
ones of said plurality of metallization layers, being configured underneath said topmost metallization layers, having ones of said plurality of signal line structures;
said first one of said plurality of voltage supply structures of said topmost metallization layers having a grid of supply interconnects configured parallel to one another;
said second one of said plurality of voltage supply structures of said topmost metallization layers having a grid of supply interconnects configured parallel to one another; and
said grid of said first one of said plurality of voltage supply structures being rotated relative to said grid of said second one of said plurality of voltage supply structures.

2. The electronic device according to claim 1, wherein:
said semiconductor chip includes an integrated circuit subdivided into a plurality of functional module regions; and
each one of said plurality of module regions has a plurality of passage contacts connecting ones of said plurality of contact areas to said first one of said plurality of voltage supply structures and to said second one of said plurality of voltage supply structures.

3. The electronic device according to claim 1, wherein:
said semiconductor chip has a silicon chip made of monocrystalline material and has an integrated circuit near said active top side;
said integrated circuit has said plurality of contact areas and a plurality of interconnects configured above said plurality of contact areas;
said plurality of interconnects of said integrated circuit and said plurality of contact areas have electrical connections therebetween;
said electrical connections are effected via said plurality of passage contacts of said plurality of insulation layers; and
said electrical connections are wired automatically using place-route programs.

4. The electronic device according to claim 1, wherein:
said supply interconnects of said grid of said first one of said plurality of voltage supply structures alternately have different electrical supply potentials; and
said supply interconnects of said grid of said second one of said plurality of voltage supply structures alternately have different electrical supply potentials.

5. The electronic device according to claim 4, wherein:
said supply interconnects of said grid of said first one of said plurality of voltage supply structures are spaced apart at distances dimensioned to provide an electrical capacitance that is as high as possible with sufficient dielectric strength; and
said supply interconnects of said grid of said second one of said plurality of voltage supply structures are spaced apart at distances dimensioned to provide an electrical capacitance that is as high as possible with sufficient dielectric strength.

6. The electronic device according to claim 1, wherein:
said supply interconnects of said grid of said first one of said plurality of voltage supply structures all have a first electrical supply potential; and
said supply interconnects of said grid of said second one of said plurality of voltage supply structures all have a second electrical supply potential that is different from said first electrical supply potential.

7. The electronic device according to claim 1, wherein ones of said plurality of insulation layers located between said topmost metallization layers have a thickness dimensioned to provide an electrical capacitance that is as high as possible with sufficient dielectric strength at areas of said topmost metallization layers that are configured one above another.

8. The electronic device according to claim 1, wherein said plurality of metallization layers include polycrystalline silicon, copper, aluminum, nickel, an alloy of copper, an alloy of aluminum, or an alloy of nickel.

9. The electronic device according to claim 1, wherein said plurality of insulation layers include silicon dioxide, silicon nitride, or polymeric plastics.

10. The electronic device according to claim 1, wherein:
said plurality of signal line structures have interconnects with a thickness and a width;
said supply interconnects of said grid of said first one of said plurality of voltage supply structures have a thickness and a width that are greater than said thickness and said width of said interconnects of said plurality of signal line structures; and
said supply interconnects of said grid of said second one of said plurality of voltage supply structures have a thickness and a width that are greater than said thickness and said width of said interconnects of said plurality of signal line structures.

11. A semiconductor wafer, comprising:
an active top side having a plurality of contact areas;
a plurality of semiconductor chip positions configured in rows and columns on said active top side;
each one of said plurality of semiconductor chip positions having a plurality of patterned metallization layers and a plurality of insulation layers configured alternately one above another, said plurality of insulation layers having a plurality of passage contacts, said plurality of metallization layers having a plurality of voltage supply structures and/or a plurality of signal line structures, said plurality of passage contacts configured in said insulation layers connecting said plurality of voltage supply structures and/or said plurality of signal line structures of said metallization layers to said plurality of contact areas on said active top side;
in each one of said plurality of semiconductor chip positions, said plurality of metallization layers including topmost metallization layers having area-covering ones of said plurality of voltage supply structures;
in each one of said plurality of semiconductor chip positions, said topmost metallization layers having at least a first one of said plurality of voltage supply structures for a low supply potential and a second one of said plurality of voltage supply structures for a high supply potential, said first one of said plurality of voltage supply structures being insulated from said second one of said plurality of voltage supply structures;
each one of said plurality of semiconductor chip positions including a contact wire layer and a plurality of module regions configured below said topmost metallization layers;
in each one of said plurality of semiconductor chip positions, said topmost metallization layers having a plurality of passage contacts for electrically connecting said first one of said plurality of voltage supply structures and said second one of said plurality of voltage supply structures to said plurality of module regions via said contact wire layer;
in each one of said plurality of semiconductor chip positions, ones of said plurality of metallization layers, being configured underneath said topmost metallization layers, having ones of said plurality of signal line structures;
in each one of said plurality of semiconductor chip positions, said first one of said plurality of voltage supply structures of said topmost metallization layers having a grid of supply interconnects configured parallel to one another;
in each one of said plurality of semiconductor chip positions, said second one of said plurality of voltage supply structures of said topmost metallization layers having a grid of supply interconnects configured parallel to one another; and
in each one of said plurality of semiconductor chip positions, said grid of said first one of said plurality of voltage supply structures being rotated relative to said grid of said second one of said plurality of voltage supply structures.

12. The wafer according to claim 11, wherein:
each one of said plurality of semiconductor chip positions includes an integrated circuit subdivided into a plurality of functional module regions; and
each one of said plurality of module regions has a plurality of passage contacts connecting ones of said plurality of contact areas to said first one of said plurality of voltage supply structures and to said second one of said plurality of voltage supply structures in said one of said plurality of module regions.

13. The wafer according to claim 11, further comprising:
a silicon chip made of monocrystalline material; and
an integrated circuit near said active top side;
said integrated circuit having ones of said plurality of contact areas and a plurality of interconnects configured above said ones of said plurality of contact areas of said integrated circuit;
said plurality of interconnects of said integrated circuit and said ones of said plurality of contact areas of said integrated circuit having electrical connections therebetween;
said electrical connections effected via said plurality of passage contacts of said plurality of insulation layers; and
said electrical connections being wired automatically using place-route programs.

14. The wafer according to claim 11, wherein:
said supply interconnects of said grid of said first one of said plurality of voltage supply structures alternately have different electrical supply potentials; and
said supply interconnects of said grid of said second one of said plurality of voltage supply structures alternately have different electrical supply potentials.

15. The wafer according to claim 14, wherein:
said supply interconnects of said grid of said first one of said plurality of voltage supply structures are spaced apart at distances dimensioned to provide an electrical capacitance that is as high as possible with sufficient dielectric strength; and
said supply interconnects of said grid of said second one of said plurality of voltage supply structures are spaced apart at distances dimensioned to provide an electrical capacitance that is as high as possible with sufficient dielectric strength.

16. The wafer according to claim 11, wherein:
said supply interconnects of said grid of said first one of said plurality of voltage supply structures all have a first electrical supply potential; and
said supply interconnects of said grid of said second one of said plurality of voltage supply structures all have a second electrical supply potential that is different from said first electrical supply potential.

17. The wafer according to claim 11, wherein ones of said plurality of insulation layers located between said topmost metallization layers have a thickness dimensioned to provide an electrical capacitance that is as high as possible with sufficient dielectric strength at areas of said topmost metallization layers that are configured one above another.

18. A method for producing a semiconductor wafer, which comprises:
providing the semiconductor wafer with a plurality of semiconductor chip positions, a plurality of metallization layers having signal line structures, and a plurality of insulation layers configured in between said plurality of said metallization layers, the plurality of insulation layers having passage contacts, the signal line structures connected via the passage contacts to contact areas on an active top side of the semiconductor wafer;
applying a closed metallization layer to a topmost insulation layer of the signal line structures;
using a place-route program to automatically design positions of a grid of parallel supply interconnects serving as a first voltage supply structure and patterning the closed metallization layer to form the grid of the parallel supply interconnects;
using a place-route program to automatically design a photolithography mask;
applying an insulation layer to the first voltage supply structure and using the photolithography mask to set positions of passage contacts to the contact areas on the active top side;
using a place-route program to automatically design positions of a grid of parallel supply interconnects configured transversely to the first voltage supply structure;
applying and patterning a further metallization layer with the further grid of parallel supply interconnects configured transversely to the first voltage supply structure; and
applying a passivation layer such that contact pads, which are electrically connected to the passage contacts, are not covered by the passivation layer.

19. A method for producing a plurality of electronic devices, which comprises:
providing the semiconductor wafer produced by the method according to claim 18;
separating the semiconductor wafer into a plurality of semiconductor chips having contact pads;
applying the plurality of semiconductor chips to a leadframe with a plurality of device positions;
in each of the device positions, producing bonding connections between the leadframe and the contact pads of one of the plurality of semiconductor chips;
in each of the device positions, packaging one of the plurality of semiconductor chips in a plastic housing having external contacts; and
separating the leadframe into the plurality of electronic devices.
